(19) United States
(12) Patent Application Publication
(10) Pub. No.: US 2010/0149137 A1
(43) Pub. Date: Jun. 17, 2010

(54) PARALELL-SERIAL CONVERSION CIRCUIT, AND ELECTRONIC DEVICE USING THE CIRCUIT

(75) Inventor: Shinichi Saito, Kyoto (JP)

Correspondence Address: CANTOR COLBURN, LLP, 20 Church Street, 22nd Floor, Hartford, CT, 06103, US

(73) Assignee: ROHM CO., LTD., Kyoto (JP)

(21) Appl. No.: 12/088,143

(22) PCT Filed: Sep. 14, 2006
(86) PCT No.: PCT/JP2006/318289

§ 371 Date: Mar. 26, 2008

(30) Foreign Application Priority Data
Sep. 29, 2005 (JP) JP2005-285088

(51) Int. Cl. G09G 3/36; H03M 9/00

(52) U.S. Cl. 345/204; 341/100

(57) ABSTRACT

A parallel-serial conversion circuit in which clock frequency and data width can be flexibly configured. The parallel-serial conversion circuit converts m×n bit parallel data (m and n being natural numbers), of clock frequency f, into 1-bit serial data of clock frequency f×m×n. The first converter converts m×n bit parallel data into m-bit parallel data (Dp) of clock frequency f×n. A second converter converts the m-bit parallel data (Dp) of clock frequency f×n, outputted from the first converter, into 1-bit serial data (bout) of clock frequency f×n×m. A clock signal generation circuit respectively supplies a clock signal (CK1), of frequency f×n, to the first converter, and a clock signal (CK2), of frequency f×m×n, to the second converter.

### BACKGROUND OF THE INVENTION

1. Field of the Invention

The present invention relates to a parallel-serial conversion circuit.

2. Description of the Related Art

Plural LSIs for signal processing are installed in many electronic devices, such as mobile telephones, PDAs, DVD recorders, and the like. With regard to these electronic devices, as information processing amounts increase, amounts of data sent and received between the plural LSIs are increasing. In cases in which sending and receiving of data between the LSIs is carried out via parallel signals, increases in numbers of signal lines and of LSI pins, along with increases in bit width, become a barrier to set miniaturization.

Consequently, in recent years, data transmission is performed using Low Voltage Differential Signals (below, referred to as LVDS) (for example, refer to Patent Document 1). In data transmission using LVDS, parallel data undergoes a parallel-serial conversion using high speed clock signals, and data transfer is performed using differential signals. This type of data transmission technology using LVDS is used, for example, to reduce numbers of wires in hinge portions connecting two casings of folding mobile telephones.

Patent Document 1: Japanese Patent Application, Laid Open No. 116-104936

Patent Document 2: Japanese Patent Application, Laid Open No. 2005-244464

In parallel-serial conversion, high speed clock signals are necessary. In generating these high speed clock signals, a PLL (Phase Locked Loop) is used. This PLL multiplies and outputs an inputted reference clock signal, and is generally configured to include a phase comparator, a voltage control oscillator (below, referred to as VCO), a frequency divider, and a loop filter.

However, in the data transmission using the LVDS, a high speed clock exceeding 100 MHz is necessary. In cases in which this type of high speed clock is generated using a general PLL, it becomes necessary to set operating frequencies of the VCO and the frequency divider high. When the operating frequencies of the VCO and the frequency divider are set high, current consumed by the circuit increases, and level of difficulty in designing the circuit becomes higher.

Furthermore, a method of parallel-serial conversion can also be considered that uses multiphase clock signals, outputted from a plurality of delay circuits (inverters) composing a ring oscillator inside the VCO, with phases mutually shifted. However, in such cases, there is a problem in that circuit area of the ring oscillator becomes large, and due to the number of stages in the delay circuits, data width for which parallel-serial conversion is possible becomes fixed.

The present invention has been made in view of these types of conditions, and a general purpose thereof is to provide a parallel-serial conversion circuit in which clock frequency and data width can be flexibly configured.

An embodiment of the present invention, includes a parallel-serial conversion circuit which converts m×n bit parallel data (m and n being natural numbers), of clock frequency f, into 1-bit serial data of clock frequency f×m×n. This parallel-serial conversion circuit is provided with a first converter which converts m×n bit parallel data into m-bit parallel data, of clock frequency f×n, a second converter which converts the m-bit parallel data, of clock frequency f×n, outputted from the first converter, into 1-bit serial data of clock frequency f×n×m, and a clock signal generation circuit which respectively supplies a clock signal, of frequency f×n, to the first converter, and a clock signal, of frequency f×m×n, to the second converter.

According to this embodiment, by dividing the parallel-serial conversion into two stages, it is possible to flexibly configure the clock frequency and the data width.

The second converter may perform the parallel-serial conversion based on m multiphase clock signals whose phases are mutually shifted, at a frequency f×n. According to this embodiment, it is possible to set the frequency of the multiphase clock signals substantially at f×m×n, and also to restrict the frequency of individual signals to f×n.

The clock signal generation circuit may include a voltage control oscillator including an m-stage delay circuit, a frequency divider which divides an output signal of the voltage control oscillator by n, and a phase comparator which outputs, to the voltage control oscillator, voltage according to phase difference between an output signal of the frequency divider and a reference clock signal inputted from outside. The clock signal generation circuit may supply an output signal of the voltage control oscillator to the first converter, and also may supply an output signal of each delay circuit of the voltage control oscillator to the second converter, as a multiphase clock signal.

In such cases, by changing the division ratio of the frequency divider, it is possible to change the width of data that undergoes parallel-serial conversion, at m-bit intervals. Furthermore, since the oscillation frequency of the voltage control oscillator is f×m (Hz), it can be restrained to be lower than the clock frequency of serial data, and it is possible to reduce current consumed by the circuit.

This parallel-serial conversion circuit may be integrated on one semiconductor substrate. “Integrated” includes cases in which all component elements of the circuit are formed on the semiconductor substrate, and cases in which main component elements of the circuit are integrated, and some resistors, capacitors, or the like, for adjusting a circuit constant, may be arranged outside the semiconductor substrate. By integrating the parallel-serial conversion circuit on one LSI, the circuit area can be reduced.

This parallel-serial conversion circuit may further be provided with a differential signal transmitter circuit which converts an output signal of the parallel-serial conversion circuit to a differential signal, and outputs to a differential signal line. By performing data transmission using the differential signal, it is possible to improve noise resistance.

Another embodiment of the present invention relates to a folding electronic device. This electronic device is provided with a liquid crystal panel installed in a first casing, a computation unit, installed in a second casing, which generates all data to be displayed on the liquid crystal panel, a differential signal line laid on a connecting member connecting the first and the second casing, and the above-mentioned parallel-serial conversion circuit which performs parallel-serial conversion of the data generated by the computation unit, and transmits the data to the liquid crystal panel via the differential signal line.

According to this embodiment, it is possible to reduce power consumed by the electronic device, and to reduce the number of wires laid on the connecting member between the first casing and the second casing, and it is possible to realize set miniaturization.

It is to be noted that any arbitrary combination or rearrangement of the above-described structural components and so forth is effective as and encompassed by the present embodiments.

Moreover, this summary of the invention does not necessarily describe all necessary features so that the invention may also be a sub-combination of these described features.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a circuit diagram showing a configuration of a parallel-serial conversion circuit according to an embodiment;

FIG. 2 is a circuit diagram showing a configuration of a VCO used in the parallel-serial conversion circuit according to the present embodiment;

FIG. 3 is a circuit diagram showing a configuration example of a second converter used in the parallel-serial conversion circuit according to the present embodiment;

FIG. 4 is a time chart representing an operation state of the parallel-serial conversion circuit of FIG. 1; and

FIG. 5 is a block diagram showing a configuration of an electronic device in which an LVDS transmitter using the parallel-serial conversion circuit of FIG. 1 is installed.

### DETAILED DESCRIPTION OF THE INVENTION

Below, the present invention will be explained based on a preferred embodiment, referring to the drawings. Identical or equivalent component elements, members, and processes, shown in the various drawings, are given the same reference symbols, and repeated explanations are omitted as appropriate. Furthermore, the embodiment is an example that does not limit the invention, and all of the features and combinations thereof, described in the embodiment, are not necessarily essential items of the invention.

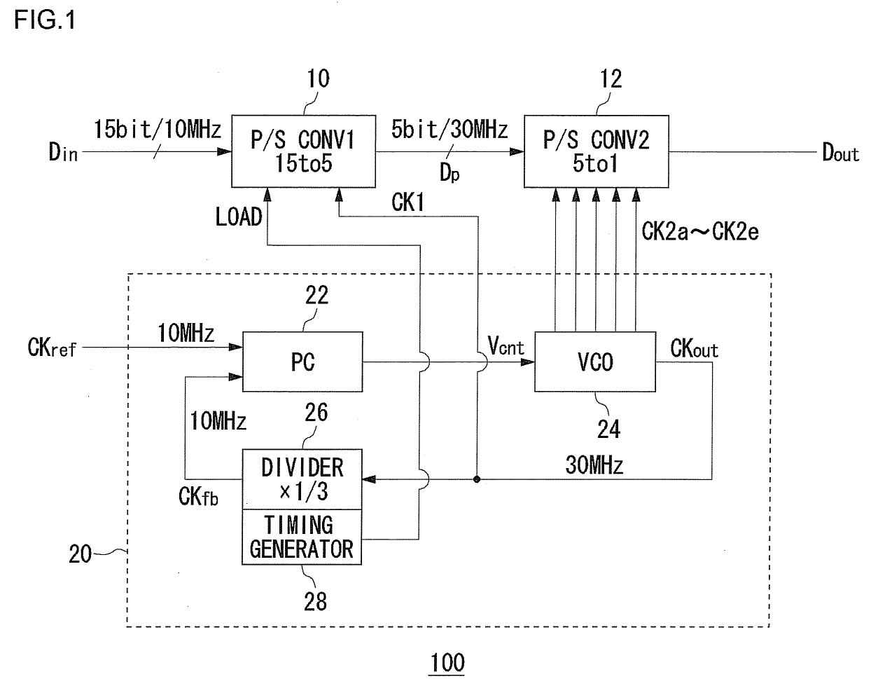

FIG. 1 is a circuit diagram showing a configuration of a parallel-serial conversion circuit 100 according to an embodiment of the present invention. This parallel-serial conversion circuit 100 performs parallel-serial conversion of parallel input data Din of data width (m×n) bits and frequency f, into 1-bit serial output data Dout. In the embodiment below, an explanation is given with m=5, n=3, f=10 MHz, as an example.

The parallel-serial conversion circuit 100 is provided with a first converter 10, a second converter 12, and a clock signal generation circuit 20. The parallel-serial conversion circuit 100 is configured so that the first converter 10, the second converter 12, and the clock signal generation circuit 20 are integrated on one semiconductor substrate. The parallel-serial conversion circuit 100 according to the present embodiment performs parallel-serial conversion by dividing in two stages, as explained below.

The parallel input data Din is inputted to the first converter 10, and m×n (=15) bit parallel data is converted into m (=5) bit parallel data Dp, of clock frequency f×n (=30 MHz).

The second converter 12 converts the 5-bit parallel data Dp, of clock frequency 30 MHz, outputted from the first converter 10, into 1-bit serial output data Dout, of clock frequency f×m×n (=150) MHz.

The clock signal generation circuit 20 supplies a clock signal CK1 of frequency f×n (=30 MHz) to the first converter 10. Furthermore, the clock signal generation circuit 20 supplies clock signals CK2 of frequency f×m×n (=150 MHz) to the second converter 12. In addition, as described later, the clock signal CK2 includes 5 clock signals, of frequency 30 MHz, with phases mutually shifted by 2π/5 each, and substantially has a frequency of 150 MHz. Below, an explanation is given concerning a configuration of the clock signal generation circuit 20.

The clock signal generation circuit 20 is configured similarly to a general PLL, and includes a phase comparator 22, a VCO 24, a frequency divider 26, and a timing generator 28. The frequency divider 26 divides the frequency of an output signal of the VCO 24 by 3 (=n). The phase comparator 22 compares an output signal CKfb of the frequency divider 26 and a reference clock signal CKref inputted from outside, and outputs a control voltage Vcnt according to a phase difference, to the VCO 24. The VCO 24 oscillates at a frequency according to the control voltage Vcnt outputted from the phase comparator 22.

In the clock signal generation circuit 20, phase difference between the reference clock signal CKref and the output signal CKfb of the frequency divider 26 returns to approach 0, and a clock signal CKout, that is the reference clock signal CKref given from outside multiplied by 3, is outputted from the clock signal generation circuit 20. Accordingly, in the present embodiment, the frequency of the clock signal CKout is 30 MHz.

The timing generator 28 generates a load signal LOAD designating timing of parallel-serial conversion of the first converter 10, based on a clock signal divided by the frequency divider 26. The load signal LOAD is outputted to the first converter 10.

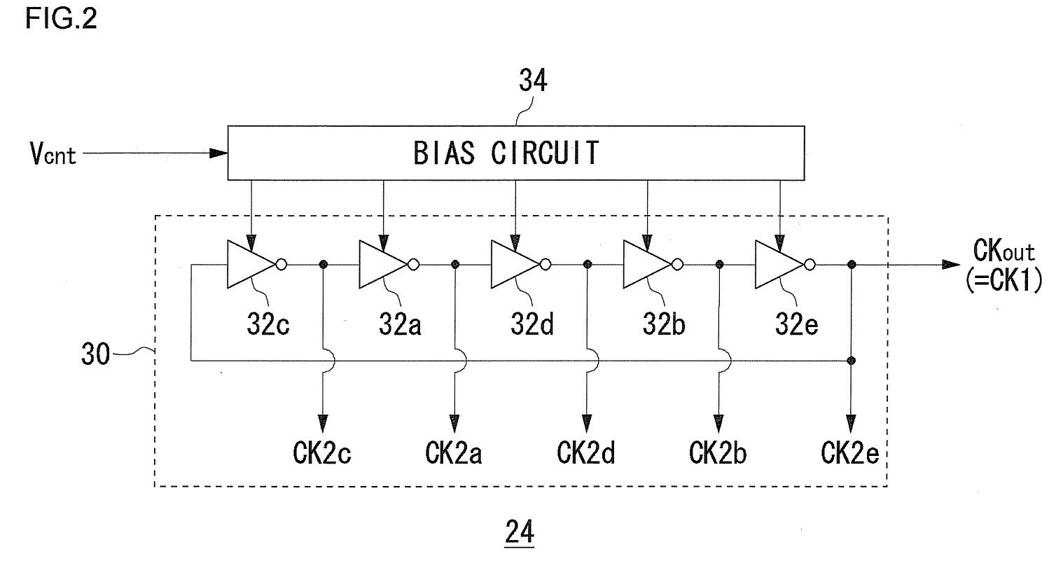

FIG. 2 is a circuit diagram showing a configuration of the VCO 24. The VCO 24 according to the present embodiment includes a ring oscillator 30, and a bias circuit 34. The ring oscillator 30 is configured of m (=5) stage delay circuits 32 connected in a longitudinal line. The delay circuits 32 are made up of inverters or the like. Below, in order to distinguish between each of the delay circuits 32 from stage 1 to stage 5, reference numerals are respectively assigned as 32c, 32a, 32d, 32b, and 32e.

The bias circuit 34 adjusts bias current of the delay circuits 32a to 32e, based on the control voltage Vcnt outputted from the phase comparator 22. As a result, an output clock signal CKout having a frequency corresponding to the control voltage Vcnt is outputted from the VCO 24. The output clock signal CKout is outputted to the first converter 10 as a clock signal CK1.

Here, attention is focused on respective output signals CK2a to CK2e of the delay circuits 32a to 32e that make up the ring oscillator 30. The output signals CK2a to CK2e are signals of frequency 30 MHz, with phases mutually shifted by 2π/m=2π/5 each. The VCO 24 outputs the output signals CK2a to CK2e to the second converter 12, as multiphase clock signals CK2. The multiphase clock signals CK2a to CK2e are signals appearing at a high level, in sequence, at time intervals of Tp=1/150 MHz, so that the substantial frequency can be considered to be 150 MHz.

The explanation now returns to FIG. 1. As described above, the frequency of the output clock signal of the VCO 24 is 30 MHz, and this is supplied to the first converter 10 as the clock signal CK1. Furthermore, output, as multiphase clock signals CK2a to CK2e outputted from the delay circuits 32a to 32e of the VCO 24, is made to the second converter 12. The first converter 10 performs parallel-serial conversion based on the clock signal CK1 and the load signal LOAD, and the second converter 12 performs parallel-serial conversion, based on the clock signals CK2.

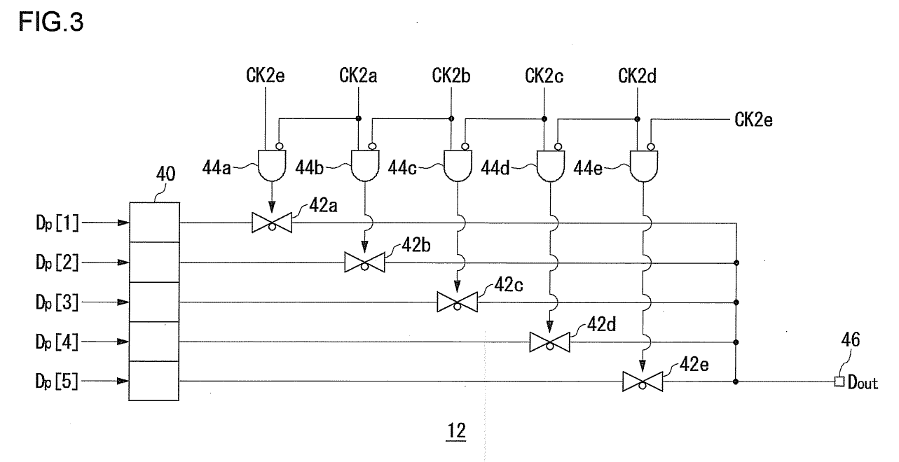

Since the first converter 10 may be configured using a general shift register, an explanation of an internal configuration is omitted. Furthermore, the second converter 12 of the parallel-serial conversion circuit 100 according to the present embodiment can be configured, for example, as shown in FIG. 3. FIG. 3 is a circuit diagram showing a configuration example of the second converter 12.

The second converter 12 includes an input unit 40, transfer gates 42a to 42e, and AND gates 44a to 44e. Parallel data Dp outputted from the first converter 10 is inputted to the input unit 40. The transfer gates 42a to 42e are arranged between the input unit 40 and an output terminal 46 of the second converter 12.

The AND gate 44a outputs a logical product of an inverse signal *CK2a of the clock signal CK2a, and the clock signal CK2e, to the transfer gate 42a. The transfer gate 42a is ON in a period in which output of the AND gate 44a has a high level, and is OFF in a low level period. In the same way, the AND gates 44b to 44e control ON and OFF states of the transfer gates 42b to 42e, based on output signals of the multiphase clock signals CK2b to CK2e.

Based on the multiphase clock signals CK2a to CK2e, parallel data Dp is converted in sequence to serial data and outputted from the output terminal 46 of the second converter 12 configured in this way.

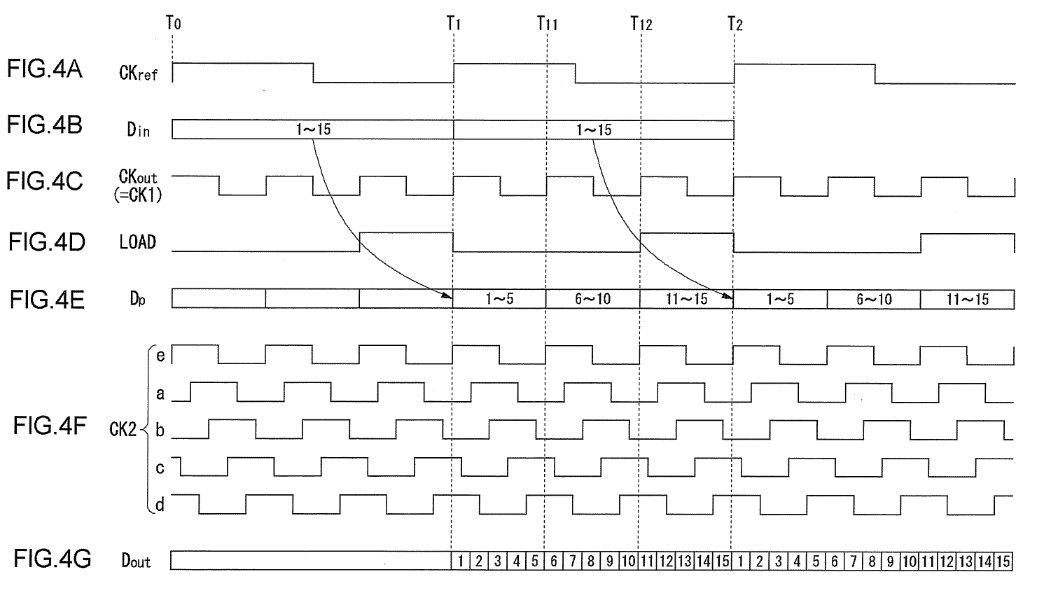

An explanation will given concerning operation of the parallel-serial conversion circuit 100 configured as above, referring to the time chart. In FIG. 4, (a) to (g) are time charts representing operation states of the parallel-serial conversion circuit 100 of FIG. 1. In FIG. 4, (a) represents the reference clock signal CKref, (b) represents the parallel input data Din, (c) represents the output clock signal CKout (=CK1) of the VCO 24, (d) represents the load signal LOAD, (e) represents the parallel data Dp, (f) represents the multiphase clock signal CK2, and (g) represents the serial output data Dout.

The parallel input data Din of (b) in the figure is inputted to the parallel-serial conversion circuit 100 synchronously with the reference clock CKref of (a). In a period from time T1 to T1 corresponding to 1 clock of the reference clock CKref, the 15-bit parallel input data Din (1 to 15) are inputted. The first converter 10 holds the parallel input data Din that was inputted, in an internal shift register.

On an occasion at time T1 when the load signal LOAD has switched from a high level to a low level, in a period from time T1 to time T2, whenever the clock signal CK1 is inputted, the first converter 10 outputs data held in first to fifth addresses of the shift register, to the second converter 12 as parallel data Dp, and furthermore sequentially shifts data held in the shift register, 5 bits each.

As shown in (c) of the same figure, the frequency of the clock signal CKout (=CK1) generated by the clock signal generation circuit 20 is a frequency 3 times the reference clock signal CKref. As a result, parallel data Dp having 5-bit data width is outputted at a frequency of 30 MHz.

The parallel data Dp inputted for each clock signal CK1 are inputted to the second converter 12. The multiphase clock signals CK2a to CK2e with mutually shifted phases, of frequency the same as the clock signal CK1, as described above, are inputted to the second converter 12. The serial output data Dout is outputted, from the second converter 12, for each transition of the multiphase clock signals CK2a to CK2e.

In this way, according to the parallel-serial conversion circuit 100 according to the present embodiment, the parallel input signal Din can undergo a parallel-serial conversion in two stages.

Here, for comparison, consideration is given to a case (below, referred to as comparison system 1) in which the parallel-serial conversion explained in the embodiment is performed with only the first converter 10. In the comparison system 1, a 15-bit shift register is implemented in the first converter 10, a 1/15 frequency divider is implemented in the clock signal generation circuit 20, a clock signal of 150 MHz is generated by the VCO, and the parallel-serial conversion is performed. In this case, since operating frequency of the VCO and the frequency divider is very high, at 150 MHz, current consumption by the circuit is high.

On the other hand, according to the parallel-serial conversion circuit 100 according to the present embodiment, the frequency of the clock signal CKout outputted from the VCO 24 is 30 MHz, and compared to the comparison system 1, the operating frequency can be decreased, and it is possible to reduce current consumption by the circuit.

Furthermore, for comparison, consideration is given to a case (below, referred to as comparison system 2) in which the parallel-serial conversion explained in the embodiment is performed with only the second converter 12. In the comparison system 2, 15 transfer gates are implemented in the second converter 12, 15-stage delay circuits are implemented in the ring oscillator VCO, and 15-phase multiphase clock signals CK2 are generated. In this case, there is a merit in that the frequency divider need not be used; however, the size of the ring oscillator becomes large, and the data width that can undergo parallel-serial conversion becomes fixed.

On the other hand, according to the parallel-serial conversion circuit 100 according to the present embodiment, by changing the division ratio of the frequency divider 26, it is possible to change the data width that can undergo parallel-serial conversion at 5-bit intervals. Furthermore, since the ring oscillator may also be made up of 5-stage delay circuits, it is possible to curtail enlargement of circuit size.

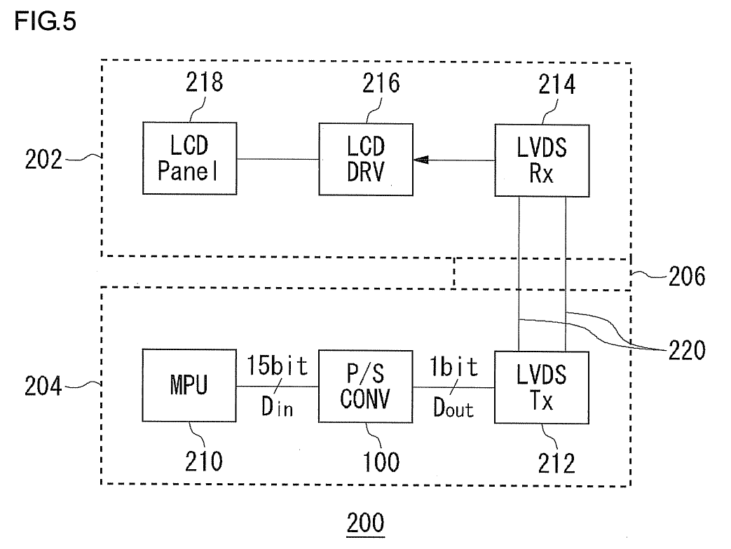

The parallel-serial conversion circuit 100 explained in the embodiment can preferably be used for data transfer using LVDS. FIG. 5 is a diagram showing a configuration of an electronic device 200 in which an LVDS transmitter using the parallel-serial conversion circuit 100 of FIG. 1 is installed. The electronic device 200 is, for example, a folding mobile telephone. The electronic device 200 is provided with a first casing 202, a second casing 204, and a connecting member 206 which connects the first casing 202 and the second casing 204.

A liquid crystal panel 218, a liquid crystal driver 216, and an LVDS receiver 214 are implemented in the first casing 202. Furthermore, a microprocessor 210, the parallel-serial conversion circuit 100, and the LVDS transmitter 212 are implemented in the second casing 204. The microprocessor 210 is a baseband IC, and generates data to be displayed on the liquid crystal panel 218. A differential signal line 220 is laid on the connecting member 206 which connects the first casing 202 and the second casing 204.

The parallel-serial conversion circuit 100 performs parallel-serial conversion on data generated by the microprocessor 210, and outputs to the LVDS transmitter 212. The LVDS transmitter 212 transmits serial data as a differential signal to the LVDS receiver 214 connected via the differential signal line 220.

The liquid crystal driver 216 drives the liquid crystal panel 218 based on the differential signal received by the LVDS receiver 214, and displays graphic data generated in the microprocessor 210.

The abovementioned embodiment is an example, and a person skilled in the art will understand that various modified examples in combinations of various component elements and various processes thereof are possible, and that such modified examples are within the scope of the present invention.

In the embodiment, an explanation was given concerning cases in which 15-bit data width parallel data undergoes parallel-serial conversion, but any number is possible, if the data width is the product m×n of natural numbers m and n. Furthermore, in the first converter 10 and the second converter 12, with regard to how many respective bits are used in the parallel-serial conversion, an appropriate configuration may be arranged according to current consumed by the circuit, circuit area, and the like.

FIG. 3 shows a configuration of the second converter 12 as one example, but there is no limitation to this in the circuit form, and the configuration may be such that sequential parallel data Dp, in accordance with the multiphase clock signals CK2, can be output as serial data.

In the embodiment, explanations have been given of cases in which the parallel-serial conversion circuit 100 is integrated, but a portion thereof may be configured as a discrete part. Decisions as to which part is integrated may be taken in accordance with cost, space occupied, usage, and the like.

1. A parallel-serial conversion circuit which converts m×n bit parallel data, in and n being natural numbers, of clock frequency f, into 1-bit serial data, of clock frequency f×m×n, the circuit comprising:
a first converter which converts the m×n bit parallel data into m-bit parallel data, of clock frequency f×n;
a second converter which converts the m-bit parallel data, of clock frequency f×n, outputted from the first converter, into 1-bit serial data, of clock frequency f×n×m; and
a clock signal generation circuit which respectively supplies a clock signal of frequency f×n, to the first converter, and a clock signal of frequency f×m×n, to the second converter.

2. A parallel-serial conversion circuit according to claim 1, wherein the second converter performs parallel-serial conversion based on in multiphase clock signals whose phases are mutually shifted, at a frequency f×n.

3. A parallel-serial conversion circuit according to claim 2, wherein the clock signal generation circuit comprises:
a voltage control oscillator including in-stage delay circuits;
a frequency divider which divides an output signal of the voltage control oscillator by n; and
a phase comparator which outputs, to the voltage control oscillator, voltage according to phase difference between an output signal of the frequency divider and a reference clock signal inputted from outside;
and the clock signal generation circuit supplies
an output signal of the voltage control oscillator to the first converter, and
an output signal of each delay circuit of the voltage control oscillator to the second converter, as a multiphase clock signal.

4. A parallel-serial conversion circuit according to claim 1, wherein the parallel-serial conversion circuit is integrated on one semiconductor substrate.

5. A parallel-serial conversion circuit according to claim 1, further comprising a differential signal transmitter circuit which converts an output signal of the parallel-serial conversion circuit into a differential signal, and outputs to a differential signal line.

6. A folding electronic device comprising:
a liquid crystal panel installed in a first casing;
a computation unit, installed in a second casing, which generates all data to be displayed on the liquid crystal panel;
a differential signal line laid on a connecting member connecting the first and the second casing; and
the parallel-serial conversion circuit according to claim 5 which performs parallel-serial conversion of the data generated by the computation unit, and transmits the data to the liquid crystal panel via the differential signal line.
